(19) United States
(12) Patent Application Publication
(10) Pub. No.: US 2026/0075697 A1
(43) Pub. Date: Mar. 12, 2026

(54) LINEAR ACCELERATOR HAVING ROBUST POWER FEEDTHROUGH

(71) Applicant: Applied Materials, Inc., Santa Clara, CA (US)

(72) Inventors: Luke Bonecutter, Cedar Park, TX (US); Kristen Stephanie Rounds, Rowley, MA (US)

(73) Assignee: Applied Materials, Inc., Santa Clara, CA (US)

(21) Appl. No.: 18/883,551

(22) Filed: Sep. 12, 2024

(51) Int. Cl. H05H 7/22; H01J 37/08; H01J 37/317; H05H 9/00

(52) U.S. Cl. CPC H05H 7/22; H01J 37/08; H01J 37/3171; H05H 9/00; H01J 2237/0473; H05H 2007/222; H05H 2007/227; H05H 2277/12

(57) ABSTRACT

A power feedthrough assembly for a linear accelerator. The power feedthrough assembly may include an insulating housing, comprising a curved ceramic shell, and a conductive rod, coupled to deliver an RF voltage to a given acceleration stage of the linear accelerator, where the conductive rod extends through an aperture in the insulating housing. The power feedthrough assembly may also include a flange, coupled to mechanically connect the insulating housing to a wall of the linear accelerator. As such, the insulating housing may include a coupling structure that couples the insulating housing to the conductive rod and to the flange, wherein the coupling structure comprises at least one protrusion configured to couple with an external structure that is located in the flange or the conductive rod.

### FIELD OF THE DISCLOSURE

The disclosure relates generally to ion implantation apparatus and more particularly to high energy beamline ion implanters.

### BACKGROUND OF THE DISCLOSURE

Ion implantation is a process of introducing dopants or impurities into a substrate via bombardment. Ion implantation systems may comprise an ion source and a series of beam-line components. The ion source may comprise a chamber where ions are generated. The ion source may also comprise a power source and an extraction electrode assembly disposed near the chamber. The beam-line components, may include, for example, a mass analyzer, a first acceleration or deceleration stage, a collimator, and a second acceleration or deceleration stage. Much like a series of optical lenses for manipulating a light beam, the beam-line components can filter, focus, and manipulate ions or ion beam having particular species, shape, energy, and/or other qualities. The ion beam passes through the beam-line components and may be directed toward a substrate mounted on a platen or clamp.

Implantation apparatus capable of generating ion energies of approximately 1 MeV or greater are often referred to as high energy ion implanters, or high energy ion implantation systems. One type of high energy ion implanter is termed linear accelerator, or LINAC, where a series of electrodes arranged as drift tubes conduct and accelerate the ion beam to increasingly higher energy along the succession of tubes, where the electrodes receive a powered voltage signal. Known LINACs are driven by an RF voltage of frequency in the MHz-GHz range.

The RF voltage that powers a given acceleration stage of a linear accelerator is supplied from a resonator assembly that includes a resonator coil having a high voltage end connected to a powered drift tube electrode. The resonator assembly includes an enclosure that may be supplied with an insulating atmosphere, such as SF6 gas, while the drift tube electrodes of the LINAC are disposed within a LINAC chamber that operates at high vacuum. The high voltage end of the resonator coil may be connected to the drift tube via a conductive structure such as a rod that extends through a wall of the LINAC chamber. In present day LINAC designs, the conductive structure may form part of a high voltage feedthrough that is designed to electrically isolate the conductive structure from grounded parts that may be in proximity to high voltage.

In present day LINAC designs the high voltage feedthroughs must support peak voltages in the range of 100 keV or greater, meaning that the conductive structure coupled to a drift tube is to be sufficiently electrically isolated from surfaces that lie at ground potential. In view of the above, there is a need to improve present day LINAC designs to ensure proper operation of high voltage feedthroughs

With respect to these and other considerations the present disclosure is provided.

### BRIEF SUMMARY

In one embodiment, a power feedthrough assembly for a linear accelerator is disclosed. The power feedthrough assembly may include an insulating housing, comprising a curved ceramic shell, and a conductive rod, coupled to deliver an RF voltage to a given acceleration stage of the linear accelerator, where the conductive rod extends through an aperture in the insulating housing. The power feedthrough assembly may also include a flange, coupled to mechanically connect the insulating housing to a wall of the linear accelerator, wherein the insulating housing comprises a coupling structure that couples the insulating housing to the conductive rod and to the flange. As such, the coupling structure may include at least one protrusion configured to couple with an external structure that is located in the flange or the conductive rod.

In another embodiment, an ion implanter is provided. The ion implanter may include an ion source to generate a continuous ion beam; and a linear accelerator, to receive the continuous ion beam, to generate a bunched ion beam therefrom, and to accelerate the bunched ion beam, the linear accelerator comprising a plurality of power feedthrough assemblies, arranged at a plurality of acceleration stages, respectively. As such, a given power feedthrough assembly may include an insulating housing, and a conductive rod, extending through the insulating housing. The power feedthrough assembly may also include a flange, coupled to mechanically connect the insulating housing to a wall of the linear accelerator, wherein the insulating housing comprises a coupling structure that couples the insulating housing to the conductive rod and to the flange. As such, the coupling structure may include at least one protrusion configured to couple with an external structure that is located in the flange or the conductive rod.

In a further embodiment, a power feedthrough assembly for a linear accelerator is provided, including an insulating housing, comprising a curved Al₂O₃ shell. The power feedthrough assembly may also include a conductive rod, coupled to deliver an RF voltage to a given acceleration stage of the linear accelerator, the conductive rod coupled to extend from a resonator through the insulating housing and into a vacuum enclosure of the linear accelerator. The power feedthrough assembly may further include a flange, coupled to mechanically connect the insulating housing to a wall of the vacuum enclosure, wherein the insulating housing comprises a coupling structure that couples the insulating housing to the conductive rod and to the flange. As such, the coupling structure may include at least one protrusion configured to couple with an external structure that is located in the flange or the conductive rod.

### BRIEF DESCRIPTION OF THE DRAWINGS

FIG. 1 shows an embodiment of an ion implanter;

FIG. 2 depicts one embodiment of a power feedthrough assembly;

FIG. 3A shows a side cross-sectional view of a power feedthrough assembly;

FIG. 3B shows a close-up view of a top region of the power feedthrough assembly of FIG. 3A;

FIG. 3C shows a close-up view of a lower region of the power feedthrough assembly of FIG. 3A;

FIG. 3D shows a top view of an insulator shim ring for use in the power feedthrough assembly of FIG. 3A;

FIG. 4A shows an isometric view of an outside of an insulating housing in accordance with some embodiments;

FIG. 4B shows an isometric view of an inside of the insulating housing of FIG. 4A; and

FIG. 4C shows side cross-sectional view of the insulating housing of FIG. 4A.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not be construed as being limited to the embodiments set forth herein. Instead, these embodiments are provided so this disclosure will be thorough and complete, and will fully convey the scope of the system and method to those skilled in the art.

Terms such as “top,” “bottom,” “upper,” “lower,” “vertical,” “horizontal,” “lateral,” and “longitudinal” may be used herein to describe the relative placement and orientation of these components and their constituent parts, with respect to the geometry and orientation of a component of a semiconductor manufacturing device as appearing in the figures. The terminology may include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are approaches for improved high energy ion implantation systems and components, based upon a beamline architecture, and in particular, ion implanters based upon linear accelerators. For brevity, an ion implantation system may also be referred to herein as an “ion implanter. ” Various embodiments entail novel approaches that provide the capability of improved control of an ion beam during acceleration through the acceleration stages of a linear accelerator, and in particular, improved ion beam focusing.

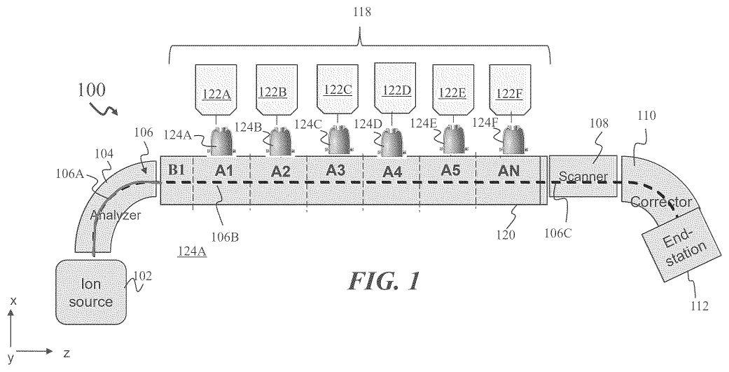

Referring now to FIG. 1, an exemplary system, shown as ion implanter 100 is shown in block form. The ion implanter 100 may represent a beamline ion implanter, with some elements not shown for clarity of explanation. The ion implanter 100 may include an ion source 102, an analyzer 104, as known in the art. The ion implanter 100 may represent a high energy ion implanter that is design to accelerate ions of a targeted ion species to a relatively higher energy, such as greater than 500 keV, greater than 1 MeV, or greater than 1.5 MeV. According to various embodiments of the disclosure, the ion implanter 100 may be designed to efficiently generate high energy ion beams for ion species over a large mass range, such as from protons up to m/q ratios of 20 or more. In addition to a linear accelerator 118, the ion implanter 100 may include a scanner 108, corrector 110, and end station 112, as known in the art. The linear accelerator 118 may include a vacuum enclosure 120 that encloses multiple internal components, such as drift tubes and quadrupoles (not separately shown) as known in the art. The vacuum enclosure 120 may form a backbone of the linear accelerator 118.

As depicted in FIG. 1, the linear accelerator 118 may be characterized by a plurality of acceleration stages. Merely for the purposes of illustration, these stages are shown as stage A1, stage A2, stage A3, stage A4, stage A5, stage AN, where N is any suitable integer. Thus, while 6 acceleration stages are depicted, in other embodiments, a linear accelerator may include fewer or a larger number of acceleration stages.

A given acceleration stage may be characterized by a power assembly that provides an RF voltage to a set of electrodes that are arranged inside the vacuum enclosure 120 as a series of drift tubes that conduct an ion beam therethrough. The power assemblies for the respective acceleration stages are shown as power assembly 122A, power assembly 122B, power assembly 122C, power assembly 122D, power assembly 122E, and power assembly 122F in the example of FIG. 1A. The different power assemblies may represent RF power supplies, circuits, and resonators to apply an RF voltage signal to each acceleration stage, as known in the art.

When an ion beam 106A is generated by the ion source 102, the ion beam 106A will enter the linear accelerator 118 as a continuous ion beam, and will be processed by a buncher B1 to generate a bunched ion beam 106B. The bunched ion beam 126B will be accelerated through the linear accelerator 118 according to the amplitude of voltage that is applied to the acceleration stages of the linear accelerator 118. The voltage applied to a given acceleration stage will generate an RF field across gaps between drift tube electrodes that are arranged with each acceleration stage, as known in the art. For example, a double gap acceleration stage may include one powered drift tube that is coupled to receive an RF signal from an RF power supply, as well as a pair of grounded drift tubes, as known in the art. A triple gap acceleration stage may include two powered drift tubes, adjacent to one another, as well as a pair of grounded drift tubes, and so forth. The voltage may be applied to a given powered drift tube via a resonator coil that is disposed in a resonator chamber of a resonator as known in the art.

Thus, as the bunched ion beam 106B is conducted through the linear accelerator 118, the bunched ion beam 106B will be accelerated through a plurality of steps to higher and higher energy that is proportional to the number of acceleration stages, the maximum voltage amplitude of the RF voltage applied to each stage, the charge of the ions of the bunched ion beam 106B, among other factors. The bunched ion beam 106B will then emerge from the linear accelerator 118 as the high energy ion beam 106C, where the final energy of the high energy ion beam 106C may be on the order of 500 keV, 1 MeV, or higher.

To deliver power to given drift tube electrodes of the given acceleration stages of the linear accelerator 118, a plurality of power feedthrough assemblies are provided. These power feedthrough assemblies are depicted as power feedthrough assembly 124A, coupled to acceleration stage A1, power feedthrough assembly 124B, coupled to acceleration stage A2, power feedthrough assembly 124C, coupled to acceleration stage A3, power feedthrough assembly 124D, coupled to acceleration stage A4, power feedthrough assembly 124E, coupled to acceleration stage A5, and power feedthrough assembly 124F, coupled to acceleration stage AN.

A function of a power feedthrough assembly is to transfer RF power from a resonator to a given drift tube, while maintaining proper electrical isolation. As detailed below, a power feedthrough assembly will bridge the environment between an ambient of a RF resonator, as represented by the power assemblies (122A-122N) and the high vacuum ambient of the inside of the vacuum enclosure 120 of the linear accelerator 118. For example, the resonator chamber of a resonator may be filled with an insulative gas, such as SF6 at a pressure above 1 atm, such as 2 atm. Moreover, the maximum voltage of an RF signal delivered to a given acceleration stage may be in excess of 100 kV. Thus, the power feedthrough assemblies (124A-124N) may be tasked with operating to transfer power to drift tubes of the linear accelerator while accommodating potential differences up to up to 130 kV, for example, while maintaining a 2 ATM pressure delta. In accordance with embodiments of the disclosure, a power feedthrough assembly is provided with novel components and component design, and materials, to meet the aforementioned challenges. These designs and materials may act to reduce high electric field stresses that would otherwise lead to early component failure, as well as acting to mitigate thermal impacts.

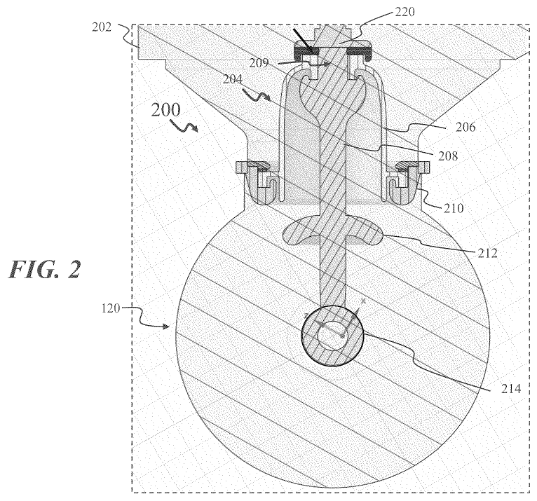

FIG. 2 depicts one embodiment of a power feedthrough assembly 200. The power feedthrough assembly 200 is arranged between a resonator enclosure 202 and the vacuum enclosure 120 of a linear accelerator. The resonator enclosure 202 represents an enclosure for a given resonator, forming part of a power assembly (see power assemblies (122A-122N)) that provides power to a given acceleration stage of a linear accelerator, such as linear accelerator 118. The power feedthrough assembly 200 may include an insulating housing 204, which housing may be formed of a curved ceramic shell 206, as shown in FIG. 2. The power feedthrough assembly 200 may further include a conductive rod 208, coupled to deliver an RF voltage to a given acceleration stage of the linear accelerator. As shown, the conductive rod 208 extends through an aperture 209 in the insulating housing 204. Note that the conductive rod 208 may include features, such as flared features, and may be integrally connected to other features, such as a drift tube electrode 214. Thus, on one distal end of the conductive rod 208, the conductive rod is electrically connected to a corresponding drift tube electrode within the vacuum enclosure 120. Accordingly, the potential of the drift tube electrode 214 will correspond to the potential on the conductive rod 208. On the other distal end of the conductive rod 208 (not explicitly shown), the conductive rod 208 will be connected with a resonator coil that has a potential oscillating according to the RF frequency applied by an RF power source. Thus, the potential on the conductive rod 208 will oscillate from a peak maximum positive voltage to a peak maximum negative voltage at a frequency, such as 13.56 MHz, or greater, such as 27.12 MHz.

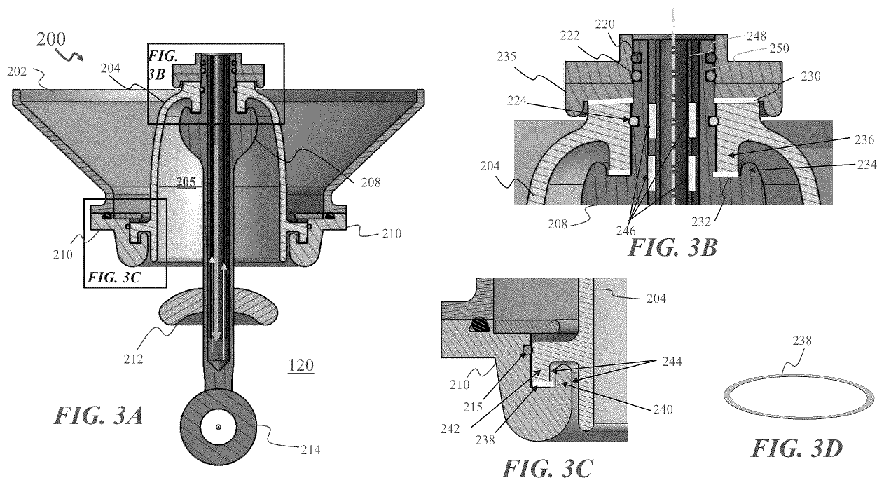

The power feedthrough assembly 200 may further include a flange 210, such as a metallic flange that is coupled to mechanically connect the insulating housing 204 to a wall of the linear accelerator, meaning a wall of the vacuum enclosure 120. As shown in FIG. 2, the insulating housing 204 may include a coupling structure that couples the insulating housing 204 to the conductive rod and to the flange 210, where the coupling structure of the insulating housing 204 includes at least one protrusion configured to interlock with an external structure that is located in the flange 210 or the conductive rod 208. In the embodiment explicitly depicted in FIG. 2, the coupling structure will be further explained with respect to FIGS. 3A-3C to follow. In some embodiments, the conductive rod 208 may further include a shield 212, as shown.

FIG. 3A shows a side cross-sectional view of a power feedthrough assembly. In this example, a variant of the power feedthrough assembly 200 is provided, with further details depicted. FIG. 3B shows a close-up view of a top region of the power feedthrough assembly of FIG. 3A. FIG. 3C shows a close-up view of a lower region of the power feedthrough assembly of FIG. 3A, while FIG. 3D shows a top view of an insulator shim ring for use in the power feedthrough assembly of FIG. 3A.

As an example, the conductive rod 208 may be hollow, with cooling channels provided to conduct a cooling fluid such as water therethrough. As shown in FIG. 3A, the insulating housing 204 includes a housing chamber 205, which housing may define a bell shape. A portion of the conductive rod 208 extends entirely through the housing chamber 205 and into the vacuum enclosure 120. As shown in FIG. 3B, the coupling structure of the insulating housing 204 includes an upper ring protrusion 236 that extends within the housing chamber 205, and extends into a circular recess 234 of the conductive rod 208. As further depicted in FIG. 3C, the insulating housing has a lower ring protrusion 242 that extends circumferentially around the housing chamber 205, and extends into a circular ridge 240 of the flange 210.

As further depicted in FIG. 3B, the power feedthrough assembly 200 may also an upper shim ring 230, formed of an electrically insulating material, and disposed around a top surface of the insulating housing 204. Moreover, the power feedthrough assembly 200 may include an inner shim ring 232, formed of an electrically insulating material and disposed between the upper ring protrusion 236 and the circular recess 234. As an example, the aforementioned shim rings may be formed of a polymer material, such as fluoropolymer, including polytetrafluoroethylene (PTFE) or similar known material. In addition, as shown in FIG. 3C, the power feedthrough assembly 200 may include a lower shim ring 238, formed of an electrically insulating material and disposed between the lower ring protrusion 242 and the circular ridge 240. The recess in the flange 210 where the lower ring protrusion 242 sits provides shielding to reduce the electric field on the triple point junction.

The aforementioned shim rings (230, 232, 238) may thus protect the ceramic/dielectric material of the insulator housing 204 from making direct contact with metal, reducing stress-risers on ceramic surfaces. In addition, as shown in FIG. 3C, the relative positioning of the lower ring protrusion 242 and the circular ridge 240 may be arranged to create gaps 244 therebetween, so that the lower ring protrusion 242 does not directly contact the circular ridge 240. Non-limiting examples of suitable dimensions for the gaps 244 include 1 mm, 2 mm, 3 mm, or 4 mm. In addition, a lower vacuum seal ring 215 may be provided so that the outer surface of the lower ring protrusion 242 is spaced apart from the flange 210.

As further shown in FIG. 3B, the power feedthrough assembly 200 may include a piston style water seal 220, disposed circumferentially around the conductive rod 208, outside of the insulating housing 204. The power feedthrough assembly 200 may also have a piston style vacuum seal 224, disposed circumferentially around the conductive rod 208, and abutting the insulating housing 204, and an RF gasket 222, disposed circumferentially around the conductive rod 208, and between the piston style water seal 220 and the piston style vacuum seal 224. The aforementioned seals and gaskets may be designed as O-ring seals, and in particular piston-style seals, including recesses in the conductive rod 208, as depicted in FIG. 2B. Thus, the conductive rod 208 does not directly abut the insulating housing as shown.

As additionally depicted in FIG. 3B, the power feedthrough assembly 200 may include a set of spacers 246, disposed between an inner fluid tube 248 and an outer wall 250 of the conductive rod 208. Note that the inner fluid tube 248 may extend into a resonator coil (not shown) to provide cooling to the resonator coil and the conductive rod 208. The inner fluid tube 248 may not be otherwise mechanically supported by the outer wall 250 of the conductive rod 208. The spacers 246 may thus provide stability to the inner fluid tube 248, ensuring that the inner fluid tube 248 does not move within the conductive rod 208 during operation. The present inventors have discovered that in the absence of the spacers 246, the inner fluid tube may move back and forth within the conductive rod 208, resulting in a fluctuation of the resonant frequency of a resonator.

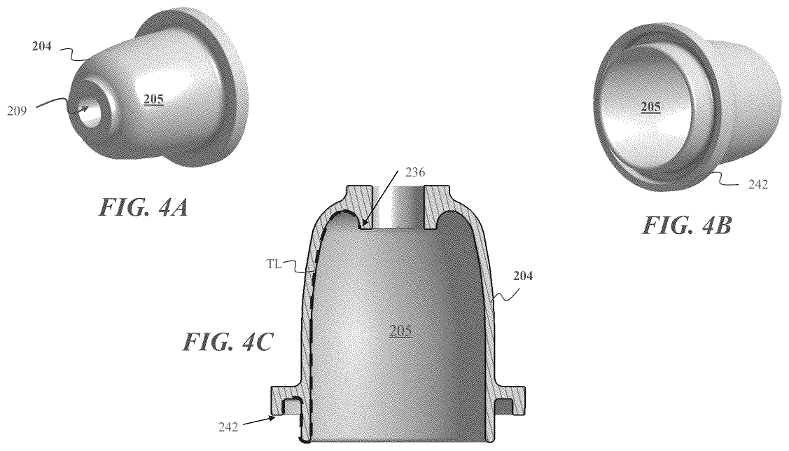

One aspect of the present embodiments involves the geometry of the insulating housing 204 relative to the circular ridge 240 that shields the triple point region from high electric field. Protrusions on the outer flange 235 and flared region of the conductive rod 208 similarly serve to shield local triple point regions where the insulator meets metallic material. Within the vacuum enclosure 120 these features provide the further benefit of creating a tortuous path to limit contaminants from coating the insulator. This geometry is further depicted in FIG. 4C that shows side cross-sectional view of the insulating housing of FIG. 4A. FIG. 4A shows an isometric view of an outside of an insulating housing 204 in accordance with some embodiments, while FIG. 4B shows an isometric view of an inside of the insulating housing of FIG. 4A. As depicted in FIG. 4C, the protrusions serve to lengthen the tracking length TL (shown in dashed curve) between conductive rod 208 and flange 210 (see FIG. 3A to view relative position of the flared part of conductive rod a 208 and flange 210), as compared to an insulating housing having a conical shape, for example.

In accordance with various embodiments of the disclosure, the insulating housing 204 may be formed of an alumina having a composition in a specific range, to provide robust performance. The present inventors have determined that an insulating housing made of alumina having a composition between 99.5% Al₂0₃ and 99.8 percent Al₂O₃ may provide a particularly suitable combination of mechanical and electrical properties to improve robust performance in the context of a power feedthrough for an RF LINAC. As an example, commercially available ceramic alumina (aluminum oxide material) having a composition of 99.3 % Al₂O₃ provides a flexural strength of 290 MPa. Note that ceramic alumina having a composition of 99.5 % Al ₂O₃ has been determined to provide a superior flexural strength of 343 MPa, while ceramic alumina having a composition of 99.6 % Al₂O₃ has been determined to provide a flexural strength of 414 MPa and ceramic alumina having a composition of 99.8 % Al₂O₃ has been determined to provide a superior flexural strength of 381 MPa. Thus, the flexural strength rapidly increases over a narrow range of composition between 99.3 % and 99.6 % Al₂O₃ and appears to peak or plateau between Al₂O₃ 99.5 % and 99.8 % Al₂O₃. Moreover, the dielectric loss tangent at an RF frequency (1 MHz) for ceramic alumina has been determined to be <1×10⁻⁴ for 99.3 % Al₂O₃, 1×10⁻⁴ for 99.5% Al₂O₃, <1×10⁻⁴ for 99.6% Al₂O₃, and 1×10⁻⁴ for 99.8% Al₂O₃. In this example, a loss tangent minimum occurs at 99.6% Al₂O₃. The above results show that an insulating housing formed of ceramic alumina having a composition in a narrow range between 99.5% Al₂O₃ and 99.8% Al₂O₃ may provide a superior combination of low dielectric loss tangent and high flexural strength, properties especially germane to performance in the context of a high voltage feedthrough for RF frequency fields in particular.

With the triple point shielding protrusions, rounded features, longer tracking length, and adequate spacing between surfaces at ground and high voltage Thus, the insulating housing 204 will be subject to relatively lower electric field stresses as compared to known power feedthrough designs, leading to less degradation of the insulating housing 204, lower chance of dielectric breakdown, and longer life.

In view of the above, a first advantage afforded by the present embodiments is the lower electric field generated in a power feedthrough, particularly in triple point regions, meaning at interfaces between dissimilar materials, as well as providing a longer tracking length. Another advantage of the present embodiments is the ability to cool the drift tubes that are coupled to the power feedthrough assemblies. Another advantage of the design of the present embodiments is the shielding against high mechanical stress points by use of protective layers between metal and ceramic, thus avoiding crack propagation in brittle ceramic materials. A further advantage of the present embodiments is the provision of shielded locations for important seals that allows the seals to be removed from high field stress areas.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. A power feedthrough assembly for a linear accelerator, comprising:
an insulating housing, comprising a curved ceramic shell;
a conductive rod, coupled to deliver an RF voltage to a given acceleration stage of the linear accelerator, the conductive rod extending through an aperture in the insulating housing; and
a flange, coupled to mechanically connect the insulating housing to a wall of the linear accelerator, wherein the insulating housing comprises a coupling structure that couples the insulating housing to the conductive rod and to the flange, wherein the coupling structure comprises at least one protrusion configured to couple with an external structure that is located in the flange or the conductive rod.

2. The power feedthrough assembly of claim 1, wherein the insulating housing comprises a housing chamber, wherein the insulating housing comprises an upper ring protrusion that extends within the housing chamber, and wherein the upper ring protrusion extends into a circular recess of the conductive rod.

3. The power feedthrough assembly of claim 1, wherein the insulating housing comprises a housing chamber, wherein the insulating housing comprises a lower ring protrusion that extends circumferentially around the housing chamber, and wherein the lower ring protrusion extends into a circular ridge of the flange.

4. The power feedthrough assembly of claim 3, wherein the insulating housing defines a bell shape, wherein the lower ring protrusion is disposed around a wide of the bell shape.

5. The power feedthrough assembly of claim 1, wherein the conductive rod is integrally connected to a powered drift tube electrode of the linear accelerator.

6. The power feedthrough assembly of claim 1, further comprising:
an upper shim ring, formed of an electrically insulating material and disposed around a top surface of the insulator housing.

7. The power feedthrough assembly of claim 2, further comprising:
an inner shim ring, formed of an electrically insulating material and disposed between the upper ring protrusion and the circular recess.

8. The power feedthrough assembly of claim 3, further comprising:
a lower shim ring, formed of an electrically insulating material and disposed between the lower ring protrusion and the circular ridge.

9. The power feedthrough assembly of claim 1, further comprising:
a piston style water seal, disposed circumferentially around the conductive rod, outside of the insulating housing;
a piston style vacuum seal, disposed circumferentially around the conductive rod, and abutting the insulating housing; and
and RF gasket, disposed circumferentially around the conductive rod, and between the piston style water seal and the piston style vacuum seal.

10. The power feedthrough assembly of claim 1, wherein the insulating housing comprises a ceramic aluminum oxide material having a purity between 99.5% and 99.8%.

11. An ion implanter, comprising:
an ion source to generate a continuous ion beam; and
a linear accelerator, to receive the continuous ion beam, to generate a bunched ion beam therefrom, and to accelerate the bunched ion beam, the linear accelerator comprising a plurality of power feedthrough assemblies, arranged at a plurality of acceleration stages, respectively, wherein a given power feedthrough assembly comprises:
an insulating housing;
a conductive rod, extending through the insulating housing; and
a flange, coupled to mechanically connect the insulating housing to a wall of the linear accelerator, wherein the insulating housing comprises a coupling structure that couples the insulating housing to the conductive rod and to the flange, wherein the coupling structure comprises at least one protrusion configured to couple with an external structure that is located in the flange or the conductive rod.

12. The ion implanter of claim 11, wherein the insulating housing comprises a housing chamber, wherein the insulating housing comprises an upper ring protrusion that extends within the housing chamber, and wherein the upper ring protrusion extends into a circular recess of the conductive rod.

13. The ion implanter of claim 11, wherein the insulating housing comprises a housing chamber, wherein the insulating housing comprises a lower ring protrusion that extends circumferentially around the housing chamber, and wherein the lower ring protrusion extends into a circular ridge of the flange.

14. The ion implanter of claim 11, further comprising:
an upper shim ring, formed of an electrically insulating material and disposed around a top surface of the insulating housing.

15. The ion implanter of claim 12, further comprising:
an inner shim ring, formed of an electrically insulating material and disposed between the upper ring protrusion and the circular recess.

16. The ion implanter of claim 13, further comprising:
a lower shim ring, formed of an electrically insulating material and disposed between the lower ring protrusion and the circular ridge.

17. The ion implanter of claim 11, further comprising:
a piston style water seal, disposed circumferentially around the conductive rod, outside of the insulating housing;
a piston style vacuum seal, disposed circumferentially around the conductive rod, and abutting the insulating housing; and
and RF gasket, disposed circumferentially around the conductive rod, and between the piston style water seal and the piston style vacuum seal.

18. The ion implanter of claim 11, wherein the insulating housing comprises a ceramic aluminum oxide material having a purity between 99.6% and 99.8%.

19. A power feedthrough assembly for a linear accelerator, comprising:
an insulating housing, comprising a curved Al₂O₃ shell;
a conductive rod, coupled to deliver an RF voltage to a given acceleration stage of the linear accelerator, the conductive rod coupled to extend from a resonator through the insulating housing and into a vacuum enclosure of the linear accelerator; and
a flange, coupled to mechanically connect the insulating housing to a wall of the vacuum enclosure, wherein the insulating housing comprises a coupling structure that couples the insulating housing to the conductive rod and to the flange, wherein the coupling structure comprises at least one protrusion configured to couple with an external structure that is located in the flange or the conductive rod.

20. The power feedthrough assembly of claim 19, wherein the
wherein the insulating housing comprises a housing chamber,
wherein the insulating housing comprises an upper ring protrusion that extends within the housing chamber,
wherein the upper ring protrusion extends into a circular recess of the conductive rod,
wherein the insulating housing comprises a lower ring protrusion that extends circumferentially around the housing chamber,
and wherein the lower ring protrusion extends into a circular ridge of the flange.
